(19) United States
(12) Patent Application Publication
(10) Pub. No.: US 2014/0353733 A1
(43) Pub. Date: Dec. 4, 2014

(54) PROTECTION OF THE GATE STACK ENCAPSULATION

(71) Applicant: GLOBAL FOUNDRIES Inc., Grand Cayman (KY)

(72) Inventors: Gabriela Dilliway, Dresden (DE); Dina H. Triyoso, Dresden (DE); Ardechir Pakfar, Dresden (DE); Markus Lenski, Dresden (DE); Dominic Thurmer, Dresden (DE)

(21) Appl. No.: 13/909,321

(22) Filed: Jun. 4, 2013

(51) Int. Cl. H01L 29/66; H01L 21/02; H01L 21/265; H01L 29/78

(52) U.S. Cl. CPC H01L 29/66477; H01L 29/78; H01L 21/02107; H01L 21/265
USPC 257/288; 438/197

(57) ABSTRACT

Semiconductor device structures at advanced technologies are provided, wherein a reliable encapsulation of a gate dielectric is already formed during very early stages of fabrication. In illustrative embodiments, a gate stack is formed over a surface of a semiconductor substrate and a sidewall spacer is formed adjacent to the gate stack for covering sidewall surfaces of the gate stack. An additional thin layer is formed over the sidewall spacer, the gate stack and the surface of the semiconductor substrate, and thereafter source/drain extension regions are implanted through the additional thin layer into the substrate in alignment with the sidewall spacer.

### BACKGROUND OF THE INVENTION

1. Field of the Invention

The present invention generally relates to encapsulating gate stacks at early stages during fabricating semiconductor devices and protection of the gate stack encapsulation. Particularly, the present invention relates to reliably encapsulating gate dielectric materials at an early stage of fabrication and protecting gate stacks during fabrication.

2. Description of the Related Art

The majority of present-day integrated circuits (ICs) are implemented by using a plurality of interconnected field effect transistors (FETs), also called metal oxide semiconductor field effect transistors (MOSFETs) or simply MOS transistors. Typically, present-day integrated circuits are implemented by millions of MOS transistors which are formed on a semiconductor substrate with a given surface area.

Basically, MOS transistors act as electronic switching elements, wherein a current through a channel region formed between source and drain regions of a MOS transistor is controlled by a gate electrode which is typically disposed over the channel region, independent from whether a PMOS transistor or an NMOS transistor is considered. Particularly, the conductivity state of a transistor is changed by a voltage applied to the gate electrode passing a so-called threshold voltage (Vt). In general, the threshold voltage depends nontrivially on the transistor's properties, such as size, material, etc.

However, as semiconductor devices and device features have become smaller in order to comply with requirements set by advanced integration densities, conventional fabrication techniques have been pushed to their limits, challenging their abilities to produce finely defined features at presently required scales. Consequently, developers are faced at each scale with problems and constraints imposed by scaling limitations which arise with semiconductor devices continuing to decrease in size.

A severe issue met by developers when attempting to exceed current technology nodes is given by constraints on maximum thicknesses of gate dielectrics in advanced gate electrodes set by the requirement of implementing a sufficiently high capacitive coupling between the gate electrode and the underlying channel region so as to reliably control a conductivity state of the channel region, while suppressing leakage currents of the gate electrode into the channel region through the gate dielectric. With decreasing gate length, this becomes an increasingly critical issue because the capacitive coupling of the gate electrode to the channel region strongly depends on the thickness of the gate dielectric. Particularly, for maintaining a sufficiently high capacitive coupling, a gate dielectric with a sufficiently small thickness has to be provided. On the other hand, the probability of tunneling of charge-carriers through the gate dielectric and, therefore, the presence of a tunneling current between gate electrode and channel region increases with decreasing thickness of the gate dielectric. This situation has been addressed by using so-called high-k dielectrics having k-values greater than 5 which allow, on the one hand, to increase the thickness of the gate dielectric so as to reduce the tunneling currents, while, on the other hand, maintaining a sufficiently high capacitive coupling between the gate electrode and the channel region due to its high electrical permeability.

Typically, high-k gate dielectric materials are very sensitive to manufacturing environments, such as high temperatures, conventionally present during annealing sequences necessary for healing crystal damages caused by implantations and activation of implanted impurities, and cleaning and etching environments, which are, for example, present in various cleaning and etching processes applied at various stages during fabrication.

A conventional process flow appearing during fabrication of semiconductor devices is schematically illustrated in FIGS. 1A-1C. FIG. 1A shows a semiconductor device 100 during an early stage of fabrication, wherein a gate structure 120 is formed on a surface of a semiconductor substrate 110. The gate structure 120 is formed by a gate dielectric layer 122 and a gate electrode material layer 124 disposed on the gate dielectric 122.

As shown in FIG. 1A, a sidewall spacer forming material layer 131 is formed over the surface of the semiconductor substrate 110 and on exposed surfaces of the gate structure 120. During the process flow as schematically shown in FIG. 1A, at this stage of fabrication, an etching sequence 130 is applied to the semiconductor device 100 and particularly to the sidewall spacer forming material layer 131.

FIG. 1B shows the semiconductor device 100 after having performed the etch sequence 130 illustrated in FIG. 1A. As can be seen from FIG. 1B, in applying the etch sequence 130 to the semiconductor device 100 as illustrated in FIG. 1a, a sidewall spacer 133 is formed adjacent to the gate structure 120 such that sidewall surfaces of the gate structure 120 at opposing sides of the gate structure 120 are covered by the sidewall spacer 133. With the etch sequence 130 as shown in FIG. 1A conventionally being anisotropic, the sidewall spacer forming material layer 131 covering the surface of the semiconductor substrate 110 is removed such that the surface of the semiconductor substrate 110 at each side of the gate structure 120 is exposed as indicated by a broken line 110S1 in FIG. 1B. Even when the etching process 130 (in FIG. 1A) is exactly time-controlled, further etching of the surface 110S1 is hardly prevented because, when exposing the surface 110S1 of the semiconductor substrate 110, the etching process 130 continues to attack the surface 110S1. In the fabrication of advanced semiconductor devices, the sidewall spacer forming material layer 131 has a very small thickness approaching the order of several atom layers to some nanometers such that a very thin sidewall spacer 133 is formed. Besides, for etching back the sidewall spacer forming material 131 (see FIG. 1A) on a top surface of the gate structure 120 to expose an upper surface of the gate electrode material 124, further etching of the semiconductor substrate 110 occurs around the gate structure 120. Therefore, a material loss takes place around the gate structure 120 resulting in the exposed semiconductor substrate 110 being etched down to a depth H₁ such that the gate structure 120 is disposed on a semiconductor portion which is elevated with regard to an exposed etched surface 110S2 of the semiconductor substrate 110 at each side of the gate structure 120.

FIG. 1C shows the semiconductor device 100 during a more advanced stage of fabrication, i.e., after source/drain extension regions 142 and halo regions 144 have been formed within the semiconductor substrate 110 by means of respective implantation processes (not illustrated). At this point, it should be kept in mind that, although FIGS. 1A-1C only illustrate one semiconductor device 100 having one gate electrode 120 during a process flow for fabricating an integrated circuit structure, in practice, millions of individual semiconductor devices are to be formed on, over and in a semiconductor substrate of a given surface area. Typically, a huge variety of different devices having different conductivity types, such as NMOS and PMOS, and device flavors, such as super-low threshold voltage or SLVT devices, low threshold voltage or LVT devices, regular threshold voltage or RVT devices and high threshold voltage or HVT devices, are fabricated on a given semiconductor substrate. The person skilled in the art appreciates that formation of source/drain extension regions and halo regions of a specific conductivity type and flavor is to be performed without affecting other device types and flavors. Conventionally, source/drain extension region implantation sequences and halo region implantation sequences are accompanied with masking and cleaning sequences which are repeatedly performed until source/drain extension regions and halo regions are formed for all device types and device flavors on, over and in the semiconductor substrate. For example, the different cleaning steps which occur during the extension and halo implantation masking steps attack exposed surfaces of the semiconductor substrate 110 and of shallow trench isolations or STI's (not illustrated), resulting in a recessing of the semiconductor substrate 110, as schematically illustrated by recesses 152 and 154 in FIG. 1C, and a lowering of STI levels (not illustrated). The inventors understood that for highly-scaled semiconductor devices 100 as illustrated in FIG. 1C, the recessing of the elevated semiconductor substrate portion 115 results in a narrowing of the elevated semiconductor substrate portion 115. Consequently, the recesses 152 and 154 under-etch the gate structure 120 and, particularly for highly-scaled gate structures 120, considerably decrease a distance d1 between an exposed surface of the recess 154 and the gate dielectric 122.

The above discussion shows that a reliable encapsulation and protection of the gate dielectric 122 is not maintained for current advanced semiconductor devices, particularly for devices having a gate length of less than 100 nm, preferably less than 50 nm, more preferably less than 35 nm.

It is, therefore, desirable to provide a method which allows for reliably encapsulating gate dielectric materials at an early stage of fabrication and particularly before formation of source/drain extension regions and/or halo regions. Furthermore, it is desirable to provide a semiconductor device having a reliably encapsulated gate dielectric, particularly at least improving, if not avoiding, at least some of the above-discussed problems.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

The present invention provides a method of forming a semiconductor device structure in advanced technologies, i.e., technologies with technology nodes smaller than 100 nm, preferably smaller than 50 nm, more preferably smaller than 35 nm. In some aspects, a reliable encapsulation of a gate dielectric is already present at very early stages of fabrication. In other aspects, a semiconductor device is provided, which semiconductor device maintains a reliable encapsulation of a gate dielectric material, the reliable encapsulation already being present at early stages of fabrication.

In a first embodiment of the present disclosure, a method of forming a semiconductor device structure is provided, the method including forming a gate stack over a surface of a semiconductor substrate, the gate stack including a gate material and a gate dielectric material layer, forming a sidewall spacer adjacent to the gate stack for covering sidewall surfaces of the gate stack, forming an additional thin layer over the sidewall spacer, the gate stack and the surface of the semiconductor substrate, and thereafter forming source/drain extension regions in the semiconductor substrate by performing implantation sequences through the additional thin layer into the substrate in alignment with the sidewall spacer.

In a second embodiment of the present disclosure, a method of forming an integrated circuit structure is provided, the method including forming a plurality of semiconductor devices, wherein at least one of the plurality of semiconductor devices is fabricated by the method as defined in the first embodiment.

In a third embodiment of the present disclosure, a semiconductor device is provided, the semiconductor device including a gate stack formed over a surface of a semiconductor substrate, the gate stack including a gate material and a gate dielectric material layer, a sidewall spacer formed adjacent to the gate stack for covering sidewall surfaces of the gate stack, an additional thin layer formed on the sidewall spacer, and source/drain extension regions aligned with the additional thin layer and the sidewall spacer. Herein, an exposed surface of the semiconductor substrate which is not covered by the gate stack, the sidewall spacer and the additional thin layer is lowered relative to an unexposed surface of the semiconductor substrate, the gate stack, the sidewall spacer and the additional thin layer being disposed over the unexposed surface, and wherein a portion of the semiconductor substrate having the unexposed surface and being elevated relative to the exposed surface is free of any narrowing of the portion.

### BRIEF DESCRIPTION OF THE DRAWINGS

The disclosure may be understood by reference to the following description taken in conjunction with the accompanying drawings, in which like reference numerals identify like elements, and in which:

FIGS. 1A-1C schematically illustrate in cross-sectional views conventional process flows of fabricating semiconductor devices; and

FIGS. 2A-2D schematically illustrate in cross-sectional views a process flow according to an embodiment of the present disclosure for fabricating a semiconductor device.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure relates to semiconductor device structures and particularly to semiconductor devices such as metal oxide semiconductor devices or MOS devices. The person skilled in the art will appreciate that although the expression “MOS device” is used, no limitation to a metal-containing gate material and/or to an oxide-containing gate dielectric material is intended. Semiconductor devices of the present disclosure and particularly MOS devices as illustrated by means of some illustrative embodiments as described herein concern devices fabricated by using advanced technologies. Semiconductor devices and particularly MOS devices of the present disclosure are fabricated by technologies applied to approach technology nodes smaller than 100 nm, preferably smaller than 50 nm, more preferably smaller than 35 nm. The person skilled in the art will appreciate that the present disclosure suggests semiconductor devices and particularly MOS devices, having gate structures such as gate stacks having a gate electrode material layer and a gate dielectric material layer with a length dimension smaller than 100 nm, preferably smaller than 50 nm, more preferably smaller than 35 nm. The present disclosure suggests providing methods of achieving reliable encapsulation of gate structures at very early stages of fabrication.

The person skilled in the art understands that MOS transistors can be fabricated as P-channel MOS transistors or PMOS transistors and as N-channel transistors or NMOS transistors, and both can be fabricated with or without mobility enhancing stressor features or strain-inducing features. The person skilled in the art understands that stress and strain may be described with regard to a tensile modulus. A circuit designer can mix and match device types, using PMOS and NMOS transistors, stressed and unstressed, to take advantage of the best characteristics of each device type as they best suit the circuit being designed.

In describing the following figures, semiconductor device structures and methods for forming a semiconductor device in accordance with various exemplary embodiments of the present disclosure will be illustrated. The described process steps, procedures and materials are to be considered only as exemplary embodiments designed to illustrate to one of ordinary skill in the art methods for practicing the invention. However, it is to be understood that the invention is not to be limited to these exemplary embodiments. Illustrated portions of semiconductor devices and semiconductor device structures may include only a single MOS structure, although those skilled in the art will recognize that actual implementations of integrated circuits may include a large number of such structures. Various steps in the manufacture of semiconductor devices and semiconductor device structures are well known and so, in the interest of brevity, many conventional steps will only be mentioned briefly herein, or will be omitted entirely without providing the well-known process details.

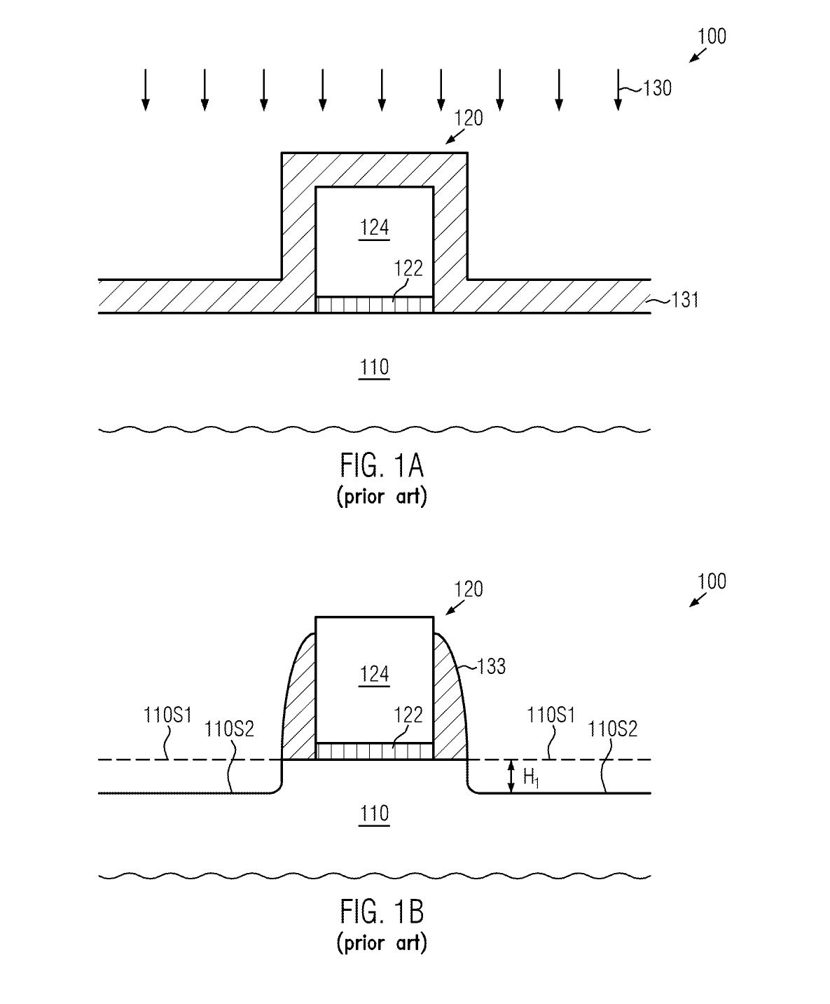

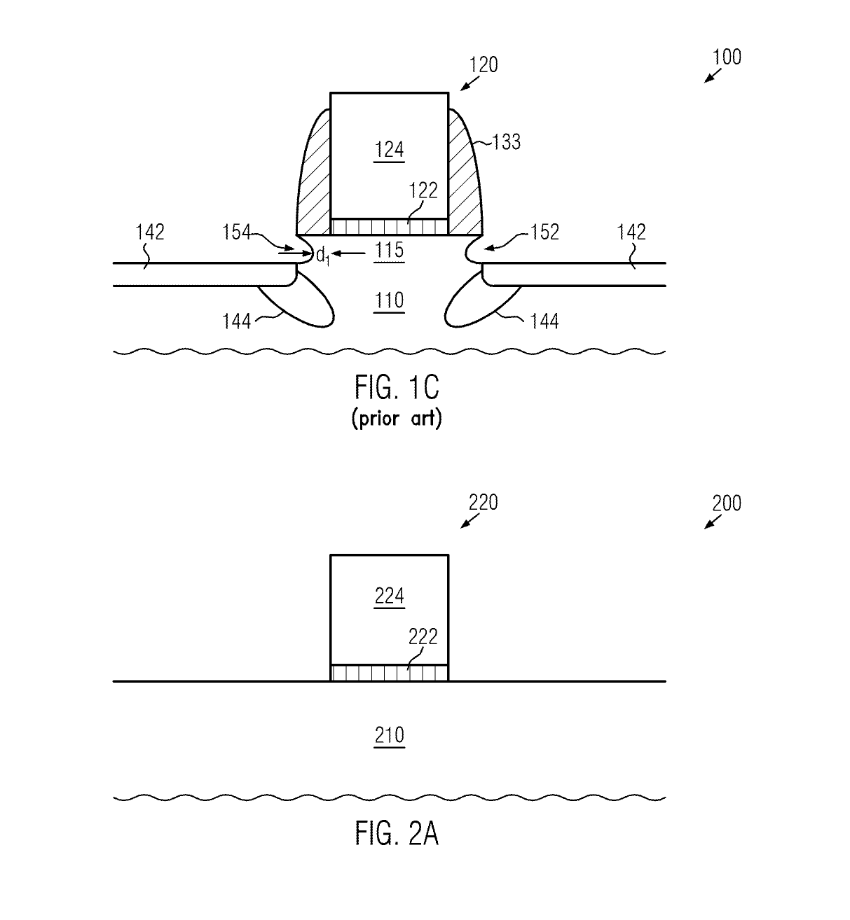

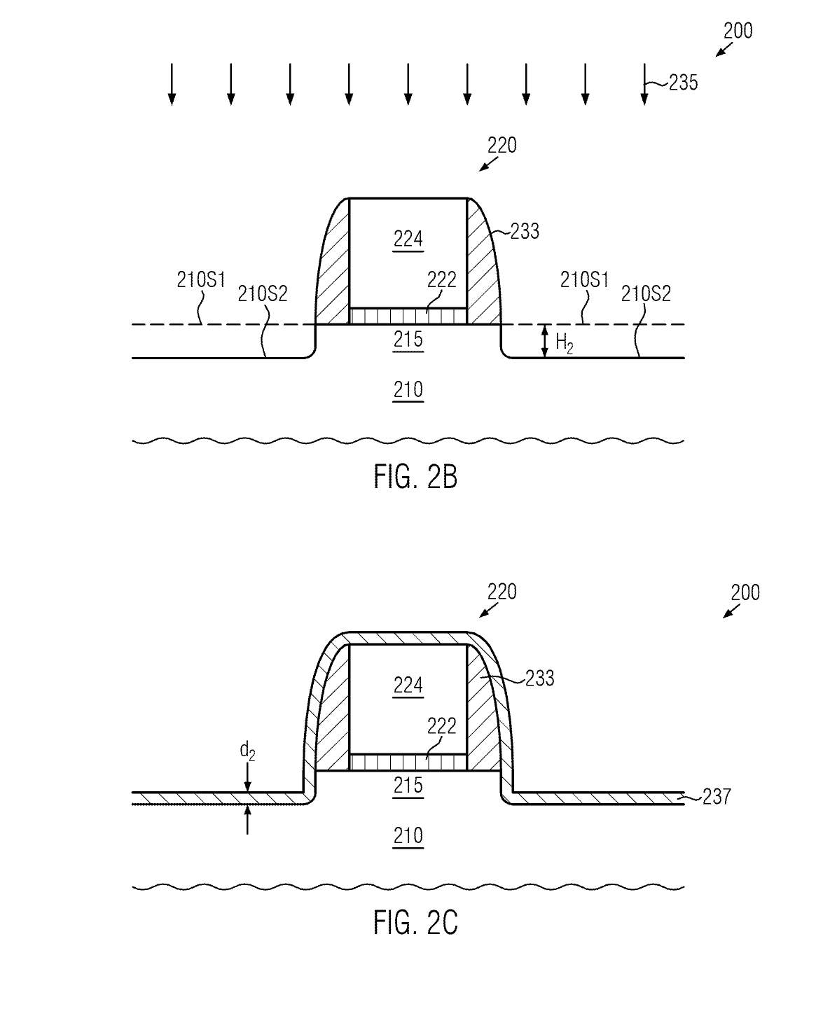

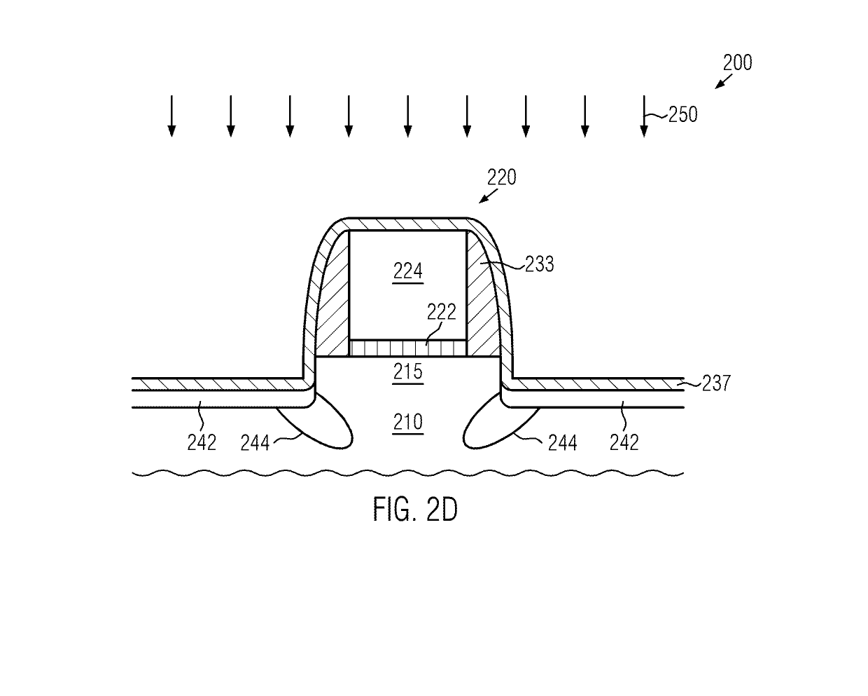

With regard to the accompanying FIGS. 2A-2D, methods and semiconductor devices according to various illustrative embodiments are now described in greater detail. It is noted that like and corresponding elements are referred to with like reference numerals and, unless explicitly stated, similar and analogous explanations as presented with regard to FIGS. 1A-1C are also applicable to the following description.

Referring to FIG. 2A, an illustrative embodiment of the present disclosure is schematically illustrated, wherein a semiconductor device 200 at an early stage of fabrication is provided, the semiconductor device 200 comprising a gate stack 220 disposed over a semiconductor substrate 210. The semiconductor substrate 210 comprises a semiconductor material which may be selected from silicon, germanium, silicon/germanium alloy, silicon/carbon alloy, silicon/germanium/carbon alloy, gallium arsenide, indium arsenide, indium phosphate, III-V compound semiconductor materials, II-VI compound semiconductor materials, organic semiconductor materials, and other appropriate compound semiconductor materials. In preferred embodiments, the semiconductor material is silicon. The person skilled in the art will appreciate that the semiconductor substrate 210 may be a single crystalline silicon layer having a surface orientation, i.e., a crystallographic orientation of the surface normal of a top surface of the semiconductor substrate 210, being one of a major crystallographic orientation. The semiconductor substrate 210 may be a bulk substrate, a semiconductor-on-insulator (SOI) substrate or a hybrid substrate. The semiconductor substrate 210 may further have a built-in stress which does not pose any limitation to the present disclosure. The semiconductor substrate 210 may be doped, such as having one or more well regions, or may not be doped.

The gate stack 220 comprises a gate dielectric material layer 222 disposed over a surface region of the semiconductor substrate 210 and a gate material 224 disposed on the gate dielectric material layer 222. The person skilled it the art will appreciate that, in some illustrative embodiments herein, the gate dielectric material layer 222 may comprise at least one of one or more high-k dielectric materials and work function adjusting materials which may be provided in a plurality of sub-layers (not illustrated) of the gate dielectric material layer 222. In some illustrative embodiments, the gate stack 220 may be implemented by a polysilicon/SiON configuration, particularly when polySiON gate devices are considered. Although not explicitly illustrated in FIG. 2A, the person skilled in the art will appreciate that a base layer of silicon oxide may be present in between the semiconductor substrate 210 and the gate dielectric material layer 222. It is further possible that the semiconductor substrate 210 has a silicon/germanium channel formed close to the surface of the semiconductor substrate 210 in case that a PMOS device is to be fabricated.

The gate stack 220 may be formed by conventional gate stack forming methods such as, for example, depositing one or more gate dielectric material layer forming materials on or over the semiconductor substrate 210, followed by further depositing a gate material on the deposited gate dielectric material layer forming material. Subsequently, one or more gate stacks may be formed by performing conventional patterning techniques, such as forming a masking structure over the gate material and performing etching processes through the masking structure, followed by cleaning processes for removing the masking structure, leaving one or more gate stacks.

FIG. 2B schematically illustrates the semiconductor device 200 according to a more advanced stage of fabrication, wherein a sidewall spacer 233 is formed adjacent to the gate stack 220 so as to cover sidewall surfaces of the gate stack 220. The sidewall spacer 233 may be formed in accordance with techniques such as described above with regard to sidewall spacer 133 in FIG. 1B. As discussed above with regard to FIG. 1B, the cleaning processes involved during the formation of the sidewall spacer 233 result in attacking the surface of the semiconductor substrate 210, i.e., an exposed surface 210S1 (indicated in FIG. 2B by a broken line) not covered by the gate stack 220 and the sidewall spacer 233. As shown in FIG. 2B, the cleaning processes performed during the formation of the sidewall spacer 233 remove material from the semiconductor substrate 210 around the gate stack 220 and the sidewall spacer 233 by etching back the exposed surface 210S1 down to an etched and recessed surface 210S2 being lowered relative to the exposed surface 210S1 by a depth H₂ as indicated by the double arrow in FIG. 2B. Therefore, the depth H₂ denotes a height of the unetched exposed surface 210S1 relative to the etched and recessed surface 210S2 of the semiconductor substrate 210 after havening finalized the sidewall spacer 233. Accordingly, the gate stack 220 is disposed over an elevated portion 215 of the semiconductor substrate 210 relative to the exposed surface 210S2. Although the schematic illustration in FIG. 2B shows a very steep and abrupt drop between the surface 210S2 and the upper surface of the elevated portion 215, this does not pose any limitation on the present disclosure as the abruptness of the drop depends on the cleaning processes applied before. Consequently, a transition portion (not illustrated) may be present between the upper surface of the elevated portion 215 and the surface 21052, the transition portion having a less abrupt inclination, other than the illustrated steep drop.

In some illustrative embodiments, the depth H₂ indicating a relative height of an unexposed surface of the semiconductor substrate 210 covered by the gate stack 220 relative to the surface 210S2 may be in the range of about 1-5 nm in cases where the semiconductor device 200 is to implement an NMOS device. In illustrative examples herein, the depth H₂ may be in the range of about 2-4.5 nm. In some specific illustrative examples herein, the depth H₂ may be in the range of about 3-4 nm. In some alternative illustrative embodiments, the depth H₂ may be in the range of about 5-15 nm in cases where the semiconductor device 200 is to implement a PMOS device. In some illustrative examples herein, the depth H₂ may be in the range of about 7-10 nm. In some specific illustrative examples, the depth H₂ may be in the range of about 7.5-9.5 nm herein.

As shown in FIG. 2B, an additional deposition process 235 is performed after having formed the sidewall spacer 233 and prior to any implantation process which is to be performed at a later stage for forming source/drain extension regions and/or halo regions and/or source/drain regions. FIG. 2C schematically illustrates the semiconductor device 200 at a stage directly after the deposition process 235 is finalized. An additional thin layer 237 is formed over the semiconductor substrate 210 and particularly on the exposed surfaces 210S2 (see FIG. 2B) of the semiconductor substrate 210, over the sidewall spacer 233 and the gate stack 220. As shown, the additional thin layer 237 covers and encapsulates the gate stack 220 and the sidewall spacer 233, while further covering the exposed surfaces 210S2.

In an illustrative embodiment herein, the additional thin layer 237 may comprise a silicon nitride material. In another illustrative embodiment, the additional thin layer 237 may comprise a silicon oxide material. The person skilled in the art will appreciate that, in selecting the material of the additional thin layer 237 so as to have a desired etch selectivity with regard to at least one of the semiconductor substrate 210 and the gate material 224 and the sidewall spacer 233, a reliable encapsulation of the gate stack 220 is achieved at a very early stage of fabrication, particularly prior to forming source/drain extension regions (see FIG. 2D).

Referring again to FIG. 2B, illustrative embodiments of the deposition process 235 are described as follows. In an illustrative embodiment, the deposition process 235 may be a low temperature depositing process. The person skilled in the art will appreciate that, in exposing the gate stack 220 to low temperatures, such as temperatures lower than 900° C., preferably lower than 750° C., more preferably lower than 600° C., the gate stack 220 is further protected from detrimental effects which may pose the gate stack integrity to any risk of being damaged. For example, when the gate dielectric material layer comprises a high-k dielectric, the quality of the gate dielectric material layer deteriorates upon exposure to temperatures other than low temperatures as high-k dielectric materials are typically very easily damaged upon exposure to high temperatures. In some illustrative examples, the deposition process 235 may be given by an atomic layer deposition (ALD) process, and preferably by a plasma enhanced ALD process. An according deposition process 235 may be performed at low temperatures, even down to room temperature, and may be configured to deposit highly conformal layers. High conformality may be understood as, e.g., a layer that has the same or approximately the same thickness everywhere where it is deposited (even in complex 3D structures, i.e., the same thickness at the bottom, top and walls of a gate stack for example). In some illustrative examples, conformality may be given by less than 25%, preferably 20%, variation around an average or median value.

In an illustrative embodiment, the deposition process 235 is controlled such that the additional thin layer 237 (FIG. 2C) is deposited with a thickness d₂, the thickness d₂ being selected such that subsequent integration steps are substantially not affected. For example, subsequent spacer formation processes may pose a risk to either the integrity of subsequently-formed spacers because spacer thicknesses depend on the desired gate channel length and/or source/drain distances which are to be implemented at later stages during fabrication. It is easy to see that additional layers having additional thicknesses affect subsequent fabrication processes if desired parameters are to be maintained.

In special illustrative examples herein, the additional thin layer 237 (FIG. 2C) may have an average thickness substantially smaller than about 10 nm, preferably smaller than about 5 nm, more preferably smaller than about 3 nm. In some illustrative example herein, the thickness d₂ may in a range of about 1-2 nm. It is noted that the expression “average thickness” indicates a thickness which is obtained by determining central tendency measures, such as measuring the thickness at a certain number of positions and calculating known measures, such as common measures of central tendency, for example, known mean values, medians and modes.

In some illustrative embodiments, the deposition process 235 is highly controlled so as to allow formation of the additional thin layer 237 to a highly conformal degree which ensures a good coverage of three-dimensional structures, i.e., structures as provided by the gate stack 220. In a special illustrative example herein, the additional thin layer 237 may show a deviation between a maximum thickness value and a minimum thickness value of the additional thin layer 237 smaller than 20%, preferably smaller than 10%, more preferably smaller than 5% or even 1%.

In some illustrative embodiments, the thickness d₂ of the additional thin layer 237 may be selected depending on a predetermined minimal length dimension of the gate stack 220 such that the minimal length dimension is substantially greater than 5 times the thickness d₂ of the additional thin layer 237, preferably greater than 7 times the thickness d₂ of the additional thin layer 237, more preferably greater than 10 times the thickness d₂ of the additional thin layer 237.

The person skilled in the art will appreciate that the thickness d₂ may be selected so as to not affect desired dimensions to be formed by extension regions and/or gate length and/or spacer thicknesses, such as a thickness of “spacer 0” and/or of “spacer 1” structures to be formed during fabrication.

FIG. 2D schematically illustrates the semiconductor device 200 in accordance with a more advanced stage during fabrication, particularly after having performed implantation processes (not illustrated) to form source/drain extension regions 242 and/or halo regions 244 within the semiconductor substrate 210 and through the additional thin layer 237. The person skilled in the art will appreciate that the additional thin layer 237 reliably encapsulates the gate stack 220, particularly the gate dielectric material layer 222, so as to protect the gate stack 220 during the implantation processes for implanting the source/drain extension regions 242 and the halo regions 244.

In some illustrative examples, subsequently, an etching process 250 may be performed in order to at least partially expose the source/drain extension regions 242 before applying further processing to form silicide regions adjacent the gate stack 220. The person skilled in the art will appreciate that, according to an illustrative embodiment herein, the etching process 250 may comprise, for example, an anisotropic etching sequence. According to a special illustrative example herein, source/drain regions may be formed in alignment with the gate stack 220 within the semiconductor substrate 210 after having performed the etching process 250. However, this does not pose any limitation to the present disclosure, and the person skilled in the art will appreciate that, instead of the etching process 250, a further spacer forming process may be performed to form another spacer (not illustrated) adjacent to the gate stack 220 and the sidewall spacer 233 as a masking structure for further source/drain implantation processes (not illustrated). The person skilled in the art will appreciate that, in according embodiments, the additional thin layer 237 is removed over the source/drain extension regions 242 during etching processes conventionally performed during further sidewall spacer-forming processes.

Some of the explicitly described illustrative embodiments relate to so called “gate-first” techniques, during which a gate electrode structure is already formed at early stages of fabrication. The person skilled in the art will appreciate that this does not pose any limitation on the present disclosure and a thin additional layer as described above may be also introduced into so-called “replacement” techniques or hybrids of “gate-first” and “replacement” techniques.

The person skilled in the art will appreciate that, in some illustrative alternative embodiments, no additional etching process may be necessary to remove the additional liner as its size may be so small that it may vanish when conventional cleaning and mask removing sequences are performed.

Some of the explicitly described illustrative embodiments describe fabrication of one MOS device. However, this does not pose any limitation on the present disclosure and the person skilled in the art will appreciate that semiconductor device structures may comprise more than one MOS device, i.e., a plurality of MOS devices, with at least one semiconductor device structure being formed by a method of the present disclosure. The person skilled in the art will understand that a plurality of MOS devices may comprise different MOS devices subjected to various performance (low; high) and/or size (smaller than 100 nm, preferably 50 nm, more preferably 35 nm; greater than 100 nm, preferably 50 nm, more preferably 35 nm) requirements. For example, some devices may be taller than others, and the recessing of a semiconductor surface around a gate structure of such taller devices may not be as critical as compared to smaller devices as discussed above. The person skilled in the art will understand that an additional thin layer may be omitted from being formed above the gate structures of taller devices. Alternatively, an additional thin layer may be formed above smaller and taller devices.

The present disclosure relates to semiconductor device structures at advanced technologies, wherein a reliable encapsulation of a gate dielectric is already formed at very early stages during fabrication. In illustrative embodiments, a gate stack is formed over a surface of a semiconductor substrate and a sidewall spacer is formed adjacent to the gate stack for covering sidewall surfaces of the gate stack. An additional thin layer is formed over the sidewall spacer, the gate stack and the surface of the semiconductor substrate, and thereafter source/drain extension regions are implanted through the additional thin layer into the substrate in alignment with the sidewall spacer.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method of forming a semiconductor device structure, comprising:
forming a gate stack over a surface of a semiconductor substrate, said gate stack comprising a gate material and a gate dielectric material layer;
forming a sidewall spacer adjacent to said gate stack for covering sidewall surfaces of said gate stack;
forming an additional thin layer over said sidewall spacer, said gate stack and said surface of said semiconductor substrate; and
thereafter, forming source/drain extension regions in said semiconductor substrate by performing an implantation sequence through said additional thin layer into said substrate in alignment with said sidewall spacer.

2. The method of claim 1, wherein forming said additional thin layer comprises performing a low thermal deposition sequence.

3. The method of claim 2, wherein said low thermal deposition sequence is performed so as to highly conformally deposit said additional thin layer by appropriately controlling said low thermal deposition sequence.

4. The method of claim 3, wherein said additional thin layer is formed by forming a silicon oxide layer.

5. The method of claim 1, wherein forming said gate stack comprises depositing a high-k dielectric material over said surface.

6. The method of claim 1, wherein forming said additional thin layer comprises forming a layer of a silicon-containing material over said sidewall spacer, said gate stack and said surface of said semiconductor substrate.

7. The method of claim 6, wherein forming said silicon-containing material comprises depositing a silicon nitride material.

8. The method of claim 6, wherein forming said silicon-containing material comprises forming a thin silicon oxide layer by performing a low thermal deposition sequence.

9. The method of claim 1, wherein forming said additional thin layer comprises forming said additional thin layer having a thickness smaller than 10 nm.

10. The method of claim 1, wherein said method further comprises removing said additional thin layer at least partially over said source/drain extension regions.

11. The method of claim 1, wherein said additional thin layer comprises a material which may be selectively etched with regard to a material of said sidewall spacer.

12. The method of claim 1, wherein forming said source/drain extension regions comprises performing cleaning sequences, wherein said cleaning sequences are adapted to said additional thin layer such that at least one of a thickness and conformity of said additional thin layer is substantially not affected.

13. A semiconductor device, comprising:
a gate stack formed over a surface of a semiconductor substrate, said gate stack comprising a gate material and a gate dielectric material layer;
a sidewall spacer formed adjacent to said gate stack for covering sidewall surfaces of said gate stack;
an additional thin layer formed on said sidewall spacer; and
source/drain extension regions aligned with said additional thin layer and said sidewall spacer;
wherein an exposed surface of said semiconductor substrate being uncovered by said gate stack, sidewall spacer and said additional thin layer is lowered relative to an unexposed surface of said semiconductor substrate, said gate stack, said sidewall spacer and said additional thin layer being disposed over said unexposed surface; and
wherein a portion of said semiconductor substrate having said unexposed surface and being elevated relative to said exposed surface is free of any narrowing of said portion.

14. The semiconductor device of claim 13, wherein said gate dielectric material comprises a high-k dielectric material.

15. The semiconductor device of claim 13, wherein said additional thin layer has an average thickness smaller than 10 nm and a deviation between a maximum thickness and a minimum thickness being smaller than 25%.

16. The semiconductor device of claim 13, wherein said additional thin layer comprises one of a silicon nitride material and a silicon oxide material.

17. The semiconductor device of claim 16, wherein said sidewall spacer comprises a silicon oxide material when said additional thin layer comprises a silicon nitride material, and said sidewall spacer comprises a silicon nitride material when said additional thin layer comprises a silicon oxide material.

18. The semiconductor device of claim 13, wherein a minimal length dimension of said unexposed surface is substantially greater than 5 times a thickness of said additional thin layer, preferably greater than 7 times a thickness of said additional thin layer or more preferably greater than 10 times a thickness of said additional thin layer.

19. The semiconductor device of claim 13, wherein a relative height of said unexposed surface with regard to said exposed surface is in the range of about 1-5 nm, preferably in the range of about 2-4.5 nm, more preferably in the range of about 3-4 nm when the semiconductor device is an NMOS device, and said relative height is in the range of about 5-15 nm, preferably in the range of about 7-10 nm, more preferably in the range of about 7.5-9.5 nm when said semiconductor device is a PMOS device.
